(19) United States
(12) Patent Application Publication
(10) Pub. No.: US 2020/0109475 A1
(43) Pub. Date: Apr. 9, 2020

(54) ETCHING METHOD

(71) Applicant: MEC COMPANY LTD., Amagasaki-shi (JP)

(72) Inventors: Yuki Ogino, Amagasaki-shi (JP); Mami Tojima, Amagasaki-shi (JP); Masahiro Hayashizaki, Amagasaki-shi (JP); Minoru Otani, Amagasaki-shi (JP)

(21) Appl. No.: 16/707,387

(22) Filed: Dec. 9, 2019

Related U.S. Application Data
(62) Division of application No. 15/550,752, filed on Aug. 11, 2017.

(30) Foreign Application Priority Data
Feb. 12, 2015 (JP) 2015-025385

(51) Int. Cl. C23F 1/26; C23F 1/44; H01L 21/3213

(52) U.S. Cl. CPC C23F 1/26; H05K 3/108; H01L 21/32133; C23F 1/44

(57) ABSTRACT

An etching method is capable of etching titanium selectively in the presence of copper. An etching liquid used in the method is low in toxicity and excellent in storage stability. The etching liquid includes at least one acid, such as, sulfuric acid, hydrochloric acid, or trichloroacetic acid, and at least one organic sulfur compound, such as a thioketone compound or a thioether compound.

### CROSS-REFERENCE TO RELATED APPLICATIONS

This application is a divisional of U.S. application Ser. No. 15/550,752, filed on Aug. 11, 2017 as the U.S. National Phase under 35. U.S.C. § 371 of International Application PCT/JP2016/051690, filed Jan. 21, 2016, which claims priority to Japanese Patent Application No. 2015-025385, filed Feb. 12, 2015. The disclosures of the above-described applications are hereby incorporated by reference in their entirety.

### TECHNICAL FIELD

The present invention relates to an etching liquid for etching titanium selectively in the presence of copper, and an etching method using this etching liquid.

### BACKGROUND ART

Hitherto, for the etching of titanium, an etching liquid containing hydrofluoric acid or hydrogen peroxide has been used. For example, Patent Document 1 suggests an etching liquid for etching titanium in the presence of copper or aluminum, the pH of this liquid being adjusted into the range of 7 to 9 with an aqueous solution including 10 to 40% by weight of hydrogen peroxide, 0.05 to 5% by weight of phosphoric acid, 0.001 to 0.1% by weight of a phosphonic acid-based compound, and ammonia.

However, the etching liquid containing hydrofluoric acid has a problem of being high in toxicity. The etching liquid containing hydrogen peroxide has a problem of being poor in storage stability.

### PRIOR ART DOCUMENT

### Patent Document

Patent Document 1: Japanese Patent No. 4471094

### SUMMARY OF THE INVENTION

### Problems to be Solved by the Invention

In the light of the above-mentioned actual situation, the present invention has been made, and an object thereof is to provide an etching liquid which is capable of etching titanium selectively in the presence of copper, and is further low in toxicity and excellent in storage stability; and an etching method using this etching liquid.

### Means for Solving the Problems

The etching liquid of the present invention is used to etch titanium selectively in the presence of copper, and comprises:

at least one acid selected from the group consisting of sulfuric acid, hydrochloric acid, and trichloroacetic acid; and at least one organic sulfur compound selected from the group consisting of a thioketone compound and a thioether compound.

It is preferred that the thioketone compound be at least one selected from the group consisting of thiourea, diethylthiourea, and trimethylthiourea.

It is preferred that the thioether compound be at least one selected from the group consisting of methionine, ethionine, and 3-(methylthio)propionic acid.

The etching liquid of the present invention preferably further comprises an α-hydroxycarboxylic acid, and/or a salt thereof.

It is preferred that the α-hydroxycarboxylic acid be at least one selected from the group consisting of tartaric acid, malic acid, citric acid, lactic acid, and glyceric acid.

It is preferred that the concentration of the acid(s) be from 20 to 70% by weight, and the concentration of the organic sulfur compound(s) be from 0.01 to 10% by weight. The concentration of the α-hydroxycarboxylic acid and/or the salt thereof is preferably from 0.2 to 5% by weight.

The present invention also relates to an etching method, comprising etching titanium selectively in the presence of copper by using the above-mentioned etching liquid.

### EFFECT OF THE INVENTION

The etching liquid of the present invention makes it possible to etch titanium selectively in the presence of copper. Moreover, the etching liquid of the present invention substantially contains neither hydrofluoric acid nor hydrogen peroxide to be low in toxicity and excellent in storage stability.

### MODE FOR CARRYING OUT THE INVENTION

The etching liquid of the present invention is an aqueous solution including at least one acid selected from the group consisting of sulfuric acid, hydrochloric acid, and trichloroacetic acid, and at least one organic sulfur compound selected from the group consisting of a thioketone compound and a thioether compound.

Out of these acids, sulfuric acid is preferred from the viewpoint of a low volatility of the acid, and the stability of the etching speed of the etching liquid.

The concentration of the acid(s) in the etching liquid is not particularly limited, and is preferably from 20 to 70% by weight, more preferably from 30 to 60% by weight. If the acid concentration is less than 20% by weight, the etching liquid tends not to gain a sufficient speed of etching titanium. If the acid concentration is more than 70% by weight, the safety of the etching liquid tends to become a problem.

The organic sulfur compound(s) has/have advantageous effects of functioning as a reductant and a chelating agent.

Examples of the thioketone compound include thiourea, N-alkylthioureas, N,N-dialkylthioureas, N,N′-dialkylthioureas, N,N,N′-trialkylthioureas, N,N,N′,N′-tetraalkylthioureas, N-phenylthiourea, N,N-diphenylthiourea, N,N′-diphenylthiourea, and ethylenethiourea. The alkyl group(s) of any one of the alkylthioureas is/are not particularly limited. The alkyl group(s) is/are (each) preferably an alkyl group having 1 to 4 carbon atoms. It is preferred to use, out of these examples, at least one selected from the group consisting of thiourea, diethylthiourea, and trimethylthiourea, which are each excellent in advantageous effects of functioning as a reductant or chelating agent, and in water solubility.

Examples of the thioether compound include methionine, a hydrochloride of an alkyl ester of methionine, ethionine, 2-hydroxy-4-(alkylthio) butyric acids, and 3-(alkylthio)propionic acids. The number of carbon atoms in each of the alkyl groups is not particularly limited, and is preferably from 1 to 4. These compounds may each be partially substituted with one or more hydrogen atoms, or one or more hydroxyl groups, amino groups or other groups. It is preferred to use, out of these examples, at least one selected from the group consisting of methionine, ethionine, and 3-(methylthio)propionic acid, which are each excellent in advantageous effects of functioning as a reductant or chelating agent.

The concentration of the organic sulfur compound(s) in the etching liquid is not particularly limited, and is preferably from 0.01 to 10% by weight, more preferably from 0.2 to 5% by weight. If the concentration of the organic sulfur compound(s) is less than 0.01% by weight, the etching liquid can gain neither a sufficient reducing performance nor a sufficient chelating effect so that the speed of etching titanium tends to be insufficient. If the concentration is more than 10% by weight, the dissolution of the organic sulfur compound(s) in the etching liquid tends to reach a limit.

The etching liquid may include an α-hydroxycarboxylic acid, and/or a salt thereof. The α-hydroxycarboxylic acid, and the salt thereof have advantageous effects of functioning as a chelating agent for titanium, and can therefore restrain the generation of any precipitation of titanium in the etching liquid. Examples of the α-hydroxycarboxylic acid include tartaric acid, malic acid, citric acid, lactic acid, and glyceric acid.

The concentration of the α-hydroxycarboxylic acid and/or the salt thereof in the etching liquid is not particularly limited, and is preferably from 0.2 to 5% by weight, more preferably from 0.5 to 2% by weight from the viewpoint of the chelating effect and the solubility thereof.

The etching liquid may include sulfurous acid and/or a sulfite thereof. Sulfurous acid and the sulfite thereof have advantageous effects of functioning as a reductant, and can therefore improve the speed of etching titanium.

The concentration of sulfurous acid and/or the sulfite thereof in the etching liquid is not particularly limited, and is preferably from 0.02 to 0.5% by weight, more preferably from 0.05 to 0.2% by weight from the viewpoint of the reducing performance and odor thereof.

Besides the above-mentioned components, any other component may be added to the etching liquid as far as the advantageous effects of the present invention are not hindered. Examples of the other component include a surfactant, a component stabilizer, and an antifoaming agent.

The etching liquid can easily be prepared by dissolving the above-mentioned individual components into water. The water is preferably water from which ionic substances and impurities have been removed. The species of the water is preferably, for example, ion exchange water, pure water, and super pure water.

About the etching liquid, it is allowable to blend the individual components with each other to have predetermined concentrations, respectively, when the etching liquid is used; or prepare a concentrated liquid of the etching liquid beforehand, dilute the concentrated liquid immediately before the use, and then use the diluted liquid.

An etching method using the etching liquid of the present invention is not particularly limited. Examples of the method include a method of coating or spraying the etching liquid onto a target object containing copper and titanium, and a method of immersing a target object containing copper and titanium into the etching liquid. The treatment temperature is not particularly limited, and is preferably from 40 to 70° C., more preferably 45 to 55° C. from the viewpoint of the etching speed of the etching liquid, and safety. The treatment period is varied in accordance with, for example, the surface state and shape of the target object. The period is usually from 30 to 120 seconds.

### EXAMPLES

The following will describe working examples of the present invention together with comparative examples. The invention should not be interpreted to be limited to the working examples described below.

Each etching liquid was prepared to have one out of compositions shown in Tables 1 and 2. Under conditions described below, an etching test and an etching liquid stability test were conducted. In the etching liquid of each of the compositions shown in Tables 1 and 2, the balance thereof was made of ion exchange water. Each concentration of hydrochloric acid shown in Tables 1 and 2 is the concentration of the acid as hydrogen chloride.

### (Etching Test)

A titanium film was formed into a thickness of 50 nm onto each resin piece by sputtering, and next a copper film was formed into a thickness of 200 nm onto the titanium film. Furthermore, a pattern was formed thereon by electroless plating. The resultant substrate was used as each sample. An etching liquid for copper was used to dissolve the sputtered copper film of the sample to make the titanium film naked. Thereafter, any one of the samples was immersed in the etching liquid of each of Examples 1 to 12 and Comparative Examples 1 to 3 to make an etching test. The results are shown in Table 1.

TABLE 1

| | | | Treating | Etching speed | |
|---|---|---|---|---|---|
| | | Percent | temperature | (nm/min.) | |
| | | by weight | (° C.) | Titanium | Copper |
| Example 1 | Sulfuric acid | 55 | 50 | 30 | <10 |
| | Diethylthiourea | 5 | | | |
| Example 2 | Hydrochloric acid | 30 | 50 | 35 | <10 |
| | Diethylthiourea | 5 | | | |
| Example 3 | Sulfuric acid | 55 | 50 | 50 | <10 |
| | Trimethylthiourea | 3 | | | |
| | L-lactic acid | 1 | | | |
| Example 4 | Sulfuric acid | 55 | 50 | 60 | <10 |
| | DL-methionine | 2 | | | |
| | L-lactic acid | 1 | | | |
| Example 5 | Sulfuric acid | 55 | 50 | 85 | <10 |
| | 3-(Methylthio)propionic | 2 | | | |
| | acid | | | | |
| | L-lactic acid | 1 | | | |
| Example 6 | Sulfuric acid | 55 | 50 | 35 | <10 |
| | Diethylthiourea | 5 | | | |
| | L-lactic acid | 1 | | | |
| | Sulfurous acid | 0.2 | | | |
| Example 7 | Sulfuric acid | 55 | 50 | 55 | <10 |
| | Trimethylthiourea | 3 | | | |
| | L-lactic acid | 1 | | | |
| | Sulfurous acid | 0.2 | | | |
| Example 8 | Sulfuric acid | 55 | 50 | 30 | <10 |
| | Diethylthiourea | 5 | | | |
| | Citric acid | 2 | | | |
| Example 9 | Sulfuric acid | 55 | 50 | 30 | <10 |
| | Diethylthiourea | 5 | | | |
| | Tartaric acid | 1 | | | |
| Example 10 | Sulfuric acid | 55 | 50 | 75 | <10 |
| | Ethionine | 1 | | | |
| | Tartaric acid | 1 | | | |
| Example 11 | Sulfuric acid | 50 | 50 | 90 | <10 |
| | Trichloroacetic acid | 5 | | | |
| | DL-methionine | 2 | | | |
| | Citric acid | 2 | | | |
| Example 12 | Hydrochloric acid | 30 | 50 | 40 | <10 |
| | Trimethylthiourea | 3 | | | |
| | Tartaric acid | 1 | | | |
| Comparative | Sulfuric acid | 55 | 50 | <10 | <10 |
| Example 1 | L-lactic acid | 1 | | | |
| Comparative | Diethylthiourea | 5 | 50 | <10 | <10 |
| Example 2 | L-lactic acid | 1 | | | |
| Comparative | Acetic acid | 60 | 50 | <10 | <10 |
| Example 3 | Diethylthiourea | 5 | | | |
| | L-lactic acid | 1 | | | |

As shown in Table 1, the etching liquid of the present invention makes it possible to etch titanium selectively without etching copper.

### (Stability Test of Etching Liquids)

The respective etching liquids of Examples 1, 7 and 12, and Comparative Example 4 were allowed to stand still at room temperature for 2 days, and then the same test as described above was conducted. The etching speed of each of these examples before the still standing was compared with that after the still standing. The results are shown in Table 2.

TABLE 2

| | | | | | | After still | |
|---|---|---|---|---|---|---|---|
| | | | | Before still | | standing for 2 | |
| | | | | standing | | days | |
| | | Percent | Treating | Etching speed | | Etching speed | |
| | | by | temperature | (nm/min.) | | (nm/min.) | |
| | | weight | (° C.) | Titanium | Copper | Titanium | Copper |
| Example 1 | Sulfuric acid | 55 | 50 | 30 | <10 | 30 | <10 |
| | Diethylthiorea | 5 | | | | | |
| Example 7 | Sulfuric acid | 55 | 50 | 55 | <10 | 55 | <10 |
| | Trimethylthiourea | 3 | | | | | |
| | L-lactic acid | 1 | | | | | |
| | Sulfurous acid | 0.2 | | | | | |
| Example 12 | Hydrochloric acid | 30 | 50 | 40 | <10 | 40 | <10 |
| | Trimethylthiourea | 3 | | | | | |
| | Tartaric acid | 1 | | | | | |
| Comparative | Hydrogen peroxide | 10 | 35 | 100 | <10 | 25 | <10 |
| Example 4 | Ammonia | 0.3 | | | | | |

As shown in Table 2, the etching liquids of the present invention are excellent in storage stability, and makes it possible to etch titanium selectively even after stored over a long term.

What is claimed is:

1. A method for etching titanium selectively in the presence of copper comprising:
etching the titanium in the presence of copper without etching the copper by exposing the titanium to an etching liquid comprising:
at least one acid selected from the group consisting of sulfuric acid, hydrochloric acid, and trichloroacetic acid; and
at least one organic sulfur compound selected from the group consisting of a thioketone compound and a thioether compound.

2. The etching method according to claim 1, wherein the thioketone compound is at least one selected from the group consisting of thiourea, diethylthiourea, and trimethylthiourea.

3. The etching method according to claim 1, wherein the thioether compound is at least one selected from the group consisting of methionine, ethionine, and 3-(methylthio)propionic acid.

4. The etching method according to claim 1, wherein the etching liquid further comprises an α-hydroxycarboxylic acid, and/or a salt thereof.

5. The etching method according to claim 4, wherein the α-hydroxycarboxylic acid is at least one selected from the group consisting of tartaric acid, malic acid, citric acid, lactic acid, and glyceric acid.

6. The etching method according to claim 1, wherein the concentration of the acid(s) is from 20 to 70% by weight, and the concentration of the organic sulfur compound(s) is from 0.01 to 10% by weight.

7. The etching method according to claim 4, wherein the concentration of the α-hydroxycarboxylic acid and/or the salt thereof is from 0.2 to 5% by weight.

8. The etching method according to claim 1, wherein the titanium is in the form of a film.

9. The etching method according to claim 8, further comprising forming the copper as a film on the titanium film.

10. The etching method according to claim 9, further comprising forming a pattern on the copper film.

11. The etching method according to claim 10, wherein the pattern is formed by electroless plating.

12. The etching method according to claim 11, further comprising applying an etching liquid for copper to dissolve the sputtered copper film and expose an underlying portion of the titanium film.

13. The etching method according to claim 12, wherein the etching of the titanium comprises immersing the exposed underlying portion of the titanium film in the etching liquid.
